(19) United States
(12) Patent Application Publication
(10) Pub. No.: US 2004/0111654 A1
(43) Pub. Date: Jun. 10, 2004

(54) Memory device with debug mode

(75) Inventors: Jang-Min Lin, Taipei (TW); Chung Chuan Wang, Taipei (TW)

Correspondence Address: QUINTERO LAW OFFICE, 1617 BROADWAY, 3RD FLOOR, SANTA MONICA, CA, 90404, US

(73) Assignee: Comax Semiconductor Inc.

(21) Appl. No.: 10/338,343

(22) Filed: Jan. 8, 2003

(30) Foreign Application Priority Data
Dec. 10, 2002 (TW) 91135710

(51) Int. Cl. G11C 29/00

(52) U.S. Cl. 714/718

(57) ABSTRACT

A memory device with debug mode. The memory device has a memory unit, a debug mode controller and three buffers. The memory unit accesses desired data according to an address signal and a command signal. The debug mode controller enables the three buffers to buffer address signals, command signals and the corresponding data according to an enable signal from a microprocessor, and detects whether the desired data, the address signal and the command signal change. The three buffers store the desired data, the address signal and the command signal when the desired data, the address signal and the command signal change. The microprocessor may execute a debug analysis according to the address signals, command signal, and the corresponding data stored in the three buffers of the memory device.

### BACKGROUND OF THE INVENTION

1. Field of the Invention

The present invention relates in general to a memory device. More particularly, it relates to a memory device with debug mode.

2. Description of the Related Art

Memory devices, for example 1T-SRAM or LPDRAM, are widely used to store programs or data in cell phones or personal digital assistants (PDAs). Cell phones or PDAs, however, often crash due to faulty programs or unstable conditions between hardware devices during development. Conventionally, logic analyzers are used to test faulty programs or failure data of the electronic devices, and output wave charts for analyzing and debugging. However, it is time consuming and expensive to analyze and debug faulty programs a logic analyzer. Thus, the costs of development increase.

### SUMMARY OF THE INVENTION

Accordingly, an object of the invention is to provide a memory device with debug mode and a debugging method to assist debugging and analyzing, thereby minimizing development time of new products.

Another object of the invention is to provide an electronic device having a memory device with debug mode.

In the present invention, the memory device with debug mode has a memory unit, a debug mode controller and three buffers. The memory unit accesses desired data according to an address signal and a command signal. The debug mode controller detects whether address signals, command signals and the corresponding data change and enables the three buffers to buffer address signals, command signals and the corresponding data when them change according to an external signal.

In the electronic device of the present invention, a main body has a plurality of required programs and a microprocessor outputting an enable signal to enter a debug mode. The memory unit accesses corresponding data according to an address signal and a command signal when the microprocessor executes the required programs. The debug mode controller detects whether address signals, command signals and the corresponding data change and enables the three buffers to store the address signals, command signal and the corresponding data when them change. The microprocessor executes a debug analysis according to the address signals, command signal, and the corresponding data.

### BRIEF DESCRIPTION OF THE DRAWINGS

The present invention can be more fully understood by reading the subsequent detailed description in conjunction with the examples and references made to the accompanying drawings, wherein:

FIG. 1 is a diagram of the present invention.

FIG. 2 is another diagram of the present invention.

FIG. 3 shows a flowchart of the method according to the present invention.

### DETAILED DESCRIPTION OF THE INVENTION

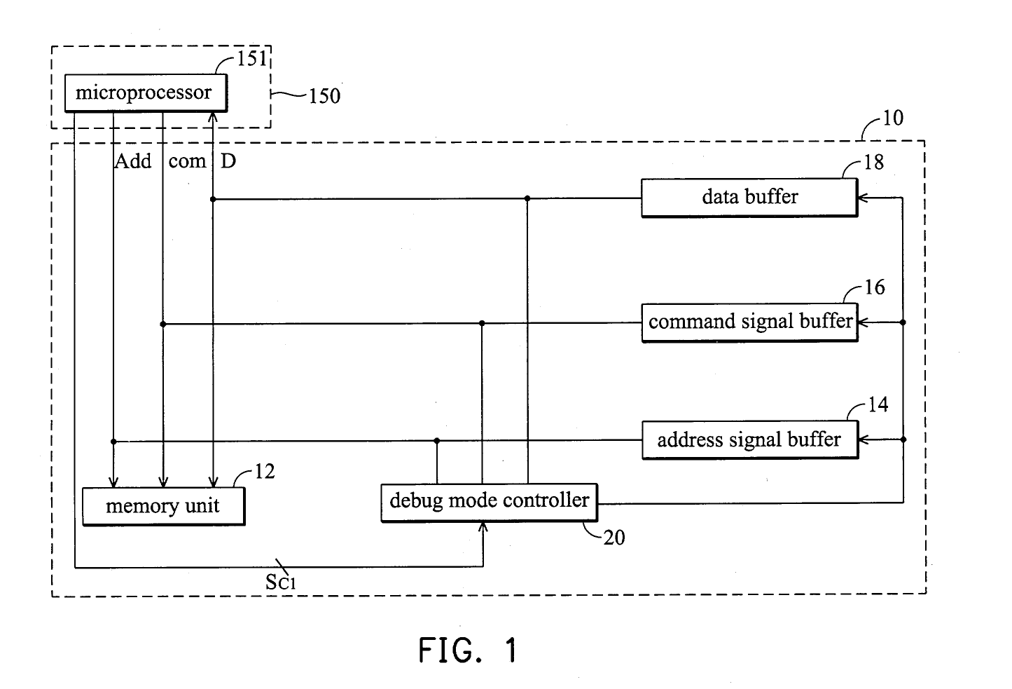

As shown in FIG. 1, the electronic device 200 having a memory device 10 with a debug mode of the present invention has a main body 150 and a memory device 20 with a debug mode.

The main body 150 is a cell phone, a personal digital assistant (PDA), or a portable consumer electronic device, and usually has a microprocessor 151, a plurality of required programs and peripheral devices such as a liquid crystal display, an input pad, a battery and the like (not shown in FIG. 1). The microprocessor 151, for example an in circuit emulation (ICE), executes the required programs according to an external control signal from external circuit. Cell phones have a microprocessor to execute required programs, for example retrieving desired data or dialing out according to information input by users.

During the developing process, testing and debugging are unable to wholly avoid product problems for users. Consequently, the microprocessor 151 of the main body 150 according to the present invention further outputs an enable signal to enter a debug mode.

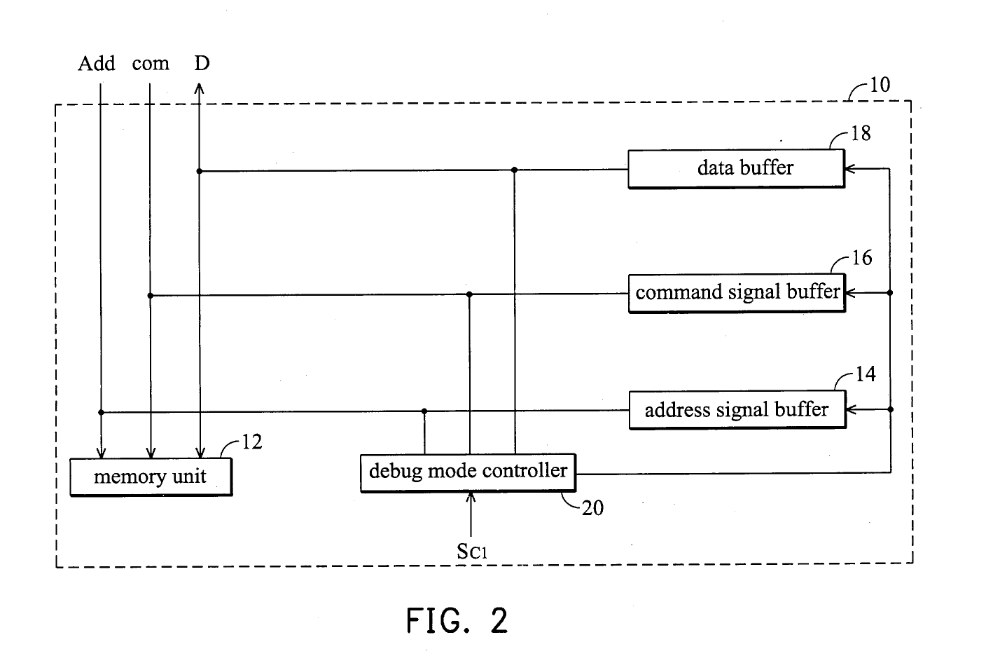

As shown in FIG. 2, the memory device 10 with a debug mode is disposed in the electronic device 200 shown in FIG. 1, and the memory device 10 has a memory unit 12, an address signal buffer 14, a command signal buffer 16, a data buffer 18, and a debug mode controller 20.

For example, the memory unit 20 has a memory array to store data, an address signal decoder to decode an address signal Add and a command signal decoder to decode a command signal com. The memory unit 20 is coupled to the microprocessor 151, and accesses corresponding data D according to a decoded address signal and a decoded command signal when the microprocessor executes required programs.

The address signal buffer 14, the command signal buffer 16 and the data buffer 18 are coupled to the memory unit 12 to buffer data. For example, each buffer 14˜18 is a shift register composed of latches or flip-flops, and each shift register stores data.

The debug mode controller 20 is coupled to the microprocessor 151, and enters into a debug mode when receiving the enable signal Sc1 from the microprocessor 151. In the debug mode, the debug mode detects whether the address signal Add, the command signal com, and the corresponding data D change, and the address signal buffer 14, the command signal buffer 16 and the data buffer 18 store the address signal Add, the command signal com, and the corresponding data D when the address signal Add, the command signal com, and the corresponding data D change.

After that, the microprocessor 151 may execute a debug analysis according to the address signal Add, the command signal com and the corresponding data D stored in the address signal buffer 14, the command signal buffer 16 and the data buffer 18.

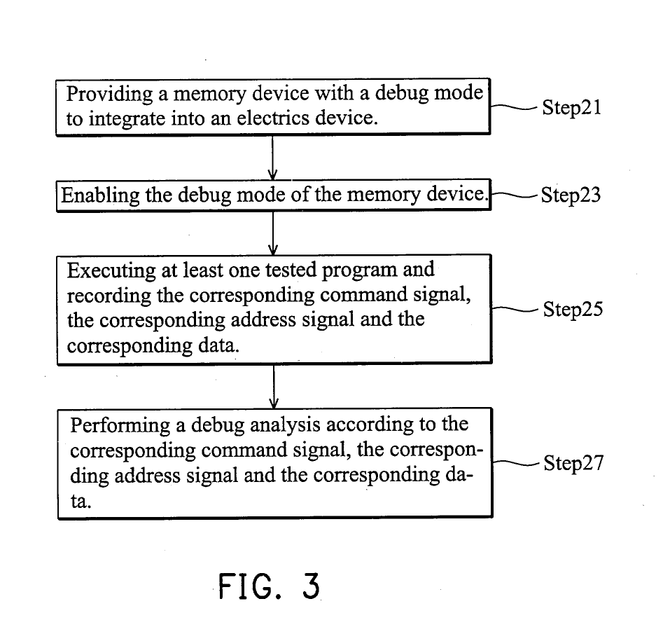

FIG. 3 is a flowchart of the method according to the present invention. In step 21, a memory device 10 with a debug mode, as shown in FIG. 2, is disposed in an electronic device 200, for example a cell phone or a PDA, with a plurality of required programs and a microprocessor 151. The microprocessor 151 executes the required programs and a debug analysis, and outputs an enable signal Sc1 to enter a debug mode. The memory device 10 has a memory unit 12 accessing corresponding data according to a decoded address signal and a decoded command signal, three buffers 14˜18 and a debug mode controller 20.

In step 23, the microprocessor 151 outputs an enable signal Sc1 to the debug mode controller 20, such that the memory device 10 enters a debug mode (the three buffers 14˜18 are turned on). In the debug mode, the debug mode controller 20 detects whether the address signal Add, the command signal com, and the corresponding data D change, and the address signal buffer 14, the command signal buffer 16 and the data buffer 18 store the address signal Add, the command signal com, and the corresponding data D when the address signal Add, the command signal com, and the corresponding data D change.

Next, in step 25, the microprocessor 151 of the electronic device 200 executes at least one tested program. The three buffers 14˜18 buffer the result address signal, the result command signal and the result data when the tested program is executed.

Finally, in step 27, the microprocessor 151 executes a debug analysis for the tested programs according to the result address signal, the result command signal and the result data stored in the buffers 14˜18.

Thus, the electronic device of the present can execute a tested program and a debug analysis without a conventional logic analyzer, and development costs and time are reduced.

The foregoing description has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A memory device with a debug mode, comprising:
a memory unit for accessing corresponding data according to an address signal and a command signal;
three buffers coupled to the memory unit; and
a debug mode controller coupled to the three buffers, detecting whether the address signal, the command signal and the corresponding data change and enabling the three buffers to buffer the address signal, the command signal, and the corresponding data when the address signal, the command signal, and the corresponding data change the according to an external signal.

2. The memory device as claimed in claim 1, wherein the memory unit comprises:
a command decoder for decoding the command signal;
an address decoder for decoding the address signal; and
a memory array for storing the corresponding data.

3. The memory device as claimed in claim 1, wherein each buffer is a shift register to store data.

4. The memory device as claimed in claim 3, wherein each shift register is composed of Flip-Flops.

5. The memory device as claimed in claim 3, wherein each shift register is composed of latches.

6. A method of debugging an electronic device, comprising;
providing a memory device with a debug mode to integrate into the electronic device, wherein the memory device has a memory unit accessing corresponding data according to an address signal and a command signal, three buffers coupled to the memory device and a debug mode controller controlling the three buffers to store the address signal, the command signal and the corresponding data;
detecting whether the address signal, the command signal and the corresponding data change;
enabling the three buffers to store the address signal, the command signal and the corresponding data when the address signal, the command signal and the corresponding data change;
reading out the address signal, the command signal and the corresponding data; and
executing a debug analysis according to the address signal, the command signal, and the corresponding data.

7. The method as claimed in claim 6, wherein the memory device comprises:
a command decoder for decoding the command signal;
an address decoder for decoding the address signal; and
a memory array for storing the corresponding data.

8. The method as claimed in claim 7, wherein each buffer is a shift register to store data.

9. The method as claimed in claim 8, wherein each shift register is composed of Flip-Flops.

10. The method as claimed in claim 8, wherein each shift register is composed of latches.

11. An electronic device, comprising:
a main body having a plurality of required programs and a microprocessor executing the required programs, wherein the control unit outputs an enable signal to enter a debug mode; and
a memory device with debug mode disposed in the electronic device, comprising:
a memory unit for accessing corresponding data according to an address signal and a command signal when the microprocessor executes the required programs;
three buffers coupled to the memory unit; and
a debug mode controller for detecting whether the address, the command signal and the corresponding data change and enabling the three buffers to store the address signal, the command signal and the corresponding data according to the enable signal; wherein the microprocessor executes a debug analysis according to the address signal, the command signal and the corresponding data stored in the three buffers.

12. The electronic device as claimed in claim 11, wherein the memory unit comprises:
a command decoder for decoding the command signal;
an address decoder for decoding the address signal; and
a memory array for storing the corresponding data.

13. The electronic device as claimed in claim 11, wherein each buffer is a shift register to store data.

14. The electronic device as claimed in claim 10, wherein each shift register is composed of Flip-Flops.

15. The electronic device as claimed in claim 10, wherein each shift register is composed of latches.

16. The electronic device as claimed in claim 11, wherein the main body is a portable electronic device.

17. The electronic device as claimed in claim 10, wherein the portable electronic device is a personal digital assistant, (PDA).

18. The electronic device as claimed in claim 10, wherein the portable electronic device is a cell phone.
